(19) United States
(12) Patent Application Publication
(10) Pub. No.: US 2016/0087194 A1
(43) Pub. Date: Mar. 24, 2016

(54) MAGNETIC TUNNEL JUNCTION DEVICE AND MAGNETORESISTIVE RANDOM ACCESS MEMORY

(71) Applicant: SAMSUNG ELECTRONICS CO., LTD., Suwon-si (KR)

(72) Inventors: Hiroyoshi ITOH, Osaka (JP); Yasuyuki KAYAMA, Yokohama (JP); Yoshiaki SONOBE, Yokohama (JP)

(21) Appl. No.: 14/857,201

(22) Filed: Sep. 17, 2015

(30) Foreign Application Priority Data
Sep. 18, 2014 (JP) 2014-190280
Sep. 18, 2014 (JP) 2014-190294
Aug. 13, 2015 (KR) 10-2015-0114744

(51) Int. Cl. H01L 43/02; H01L 43/10; G11C 11/16; H01L 43/08

(52) U.S. Cl. CPC H01L 43/02; H01L 43/08; H01L 43/10; G11C 11/161

(57) ABSTRACT

A magnetic tunnel junction device includes a memory layer having a variable magnetization direction, a fixed layer maintaining a predetermined magnetization direction, and a spacer layer, wherein the magnetic tunnel junction device performs a data writing operation by using a spin torque injection method, wherein at least one of the memory layer and the fixed layer includes a ferromagnetic insulating layer. Furthermore, the spacer layer may include current paths and an insulator.

### CROSS-REFERENCE TO RELATED APPLICATIONS

Japanese Patent Application Nos. 10-2014-0190280, filed on Sep. 18, 2014, and 10-2014-0190294, filed on September 18, and Korean Patent Application No. 10-2015-0114744, filed on Aug. 13, 2015, and entitled: “Magnetic Tunnel Junction Device and Magnetoresistive Random Access Memory,” are incorporated by reference herein in its entirety.

### BACKGROUND

1. Field

One or more embodiments described herein relate to a magnetic tunnel junction device and a magnetoresistive random access memory (MRAM).

2. Description of the Related Art

A magnetic tunnel junction (MTJ) device may perform a data reading operation based on a magnetroresistance effect and performs a data writing operation using a spin transfer torque (STT) method. This type of device includes a memory layer having a variable magnetization direction, a fixed layer that maintains a magnetization direction perpendicular to a film surface, and a tunnel barrier layer including an insulator between the memory layer and the fixed layer. In one arrangement, a ferromagnetic material having high perpendicular magnetic anisotropy and high spin polarizability may be used to form the fixed layer and memory layer. Such an MTJ device may also have a thermal disturbance resistance that correspond to microfabrication.

### SUMMARY

In accordance with one or more embodiments, a magnetic tunnel junction device includes a memory layer having a variable magnetization direction; a fixed layer maintaining a predetermined magnetization direction; and a spacer layer between the memory layer and fixed layer, wherein the magnetic tunnel junction device is to perform a data writing operation using a spin torque injection method and wherein at least one of the memory layer or the fixed layer includes a ferromagnetic insulating layer.

The memory layer and the fixed layer may include ferromagnetic insulating layers. The memory layer may include the ferromagnetic insulating layer, and the ferromagnetic insulating layer may have perpendicular magnetic anisotropy. The memory layer may include the ferromagnetic insulating layer; and a perpendicular magnetization holding layer having a magnetization direction perpendicular to a film surface.

The fixed layer may include the ferromagnetic insulating layer, and the ferromagnetic insulating layer may have perpendicular magnetic anisotropy. The fixed layer may include the ferromagnetic insulating layer; and a perpendicular magnetization holding layer having a magnetization direction perpendicular to a film surface.

The ferromagnetic insulating layer may include a ferromagnetic oxide. The ferromagnetic insulating layer may include BaFe₁₂O₁₉ or CoxFe_{3-X}O₄, 0<x<3. A device resistance value of the magnetic tunnel junction device may be about 30 Ωμm² or less.

The spacer layer may include current paths electrically connecting the memory layer to the fixed layer; and an insulator electrically insulating the memory layer from the fixed layer. The current paths may include columnar bodies having a non-magnetic metal, the insulator may include a matrix surrounding each of the current paths, and the matrix may include a non-magnetic insulator. The non-magnetic insulator may include MgO or Al₂O₃. The non-magnetic metal may include Cu.

In accordance with one or more other embodiments, a magnetoresistive random access memory includes a magnetic tunnel junction as previously described.

In accordance with one or more other embodiments, a magnetic tunnel junction device includes a memory layer having a variable magnetization direction; a fixed layer maintaining a predetermined magnetization direction; and a plurality of current paths electrically connecting the memory layer and the fixed layer, wherein at least one of the memory layer or the fixed layer includes a ferromagnetic insulating layer. The magnetic tunnel junction device may perform a data writing operation using a spin torque injection method. The ferromagnetic insulating layer may have perpendicular magnetic anisotropy.

The memory layer may include the ferromagnetic insulating layer; and a perpendicular magnetization holding layer having a magnetization direction perpendicular to a film surface. The fixed layer may include the ferromagnetic insulating layer; and a perpendicular magnetization holding layer having a magnetization direction perpendicular to a film surface.

### BRIEF DESCRIPTION OF THE DRAWINGS

Features will become apparent to those of skill in the art by describing in detail exemplary embodiments with reference to the attached drawings in which:

FIG. 1 illustrates an embodiment of an MRAM;

FIG. 2 illustrates an embodiment of an MTJ device;

FIGS. 3 and 4 illustrate an embodiment of a calculation model;

FIG. 5 illustrates an example of reverse current density for a magnetic anisotropy constant;

FIG. 6 illustrates another embodiment of an MTJ device;

FIG. 7 illustrates another embodiment of an MTJ device;

FIG. 8 illustrates another embodiment of an MTJ device;

FIG. 9 illustrates another embodiment of an MTJ device;

FIG. 10 illustrates another embodiment of an MTJ device;

FIG. 11 illustrates another embodiment of an MTJ device;

FIG. 12 illustrates another embodiment of an MTJ device;

FIG. 13 illustrates another embodiment of an MTJ device;

FIG. 14 illustrates a first example of an MTJ device;

FIG. 15 illustrates a second example of an MTJ device; and

FIG. 16 illustrates an example of a calculation model.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. The embodiments may be combined to form additional embodiments.

It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

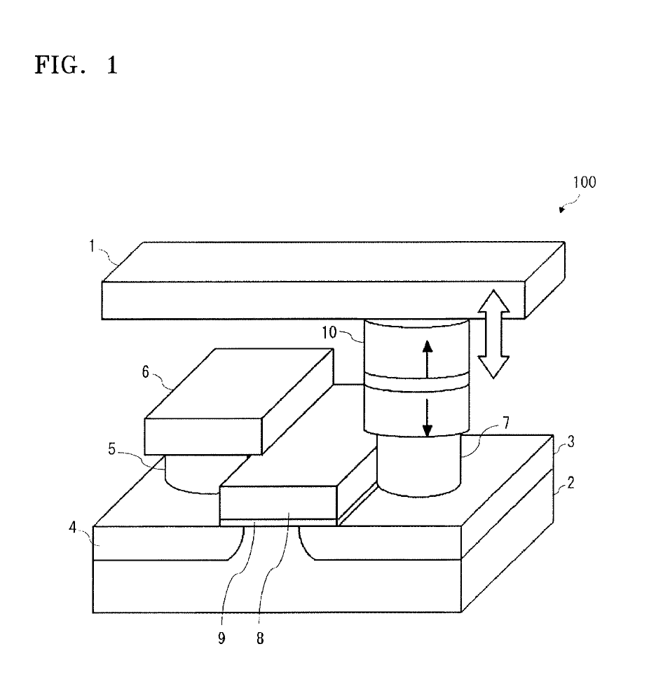

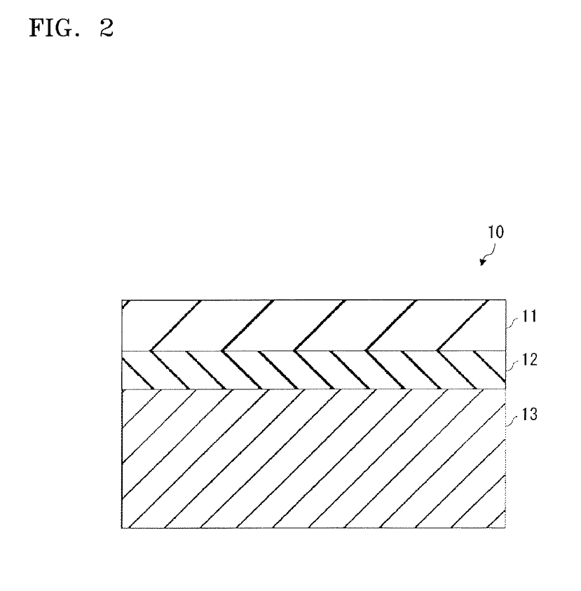

FIGS. 1 and 2 illustrate an embodiment of an MTJ device. In particular, FIG. 1 is a perspective view of a main part of a magnetoresistive random access memory (MRAM). FIG. 2 is a sectional view of the MTJ device.

As illustrated in FIG. 1, a memory cell 100 includes a semiconductor substrate 2, diffusion regions 3 and 4, a source line 6, and an MTJ device 10. An MRAM is formed by arranging a plurality of memory cells 100 in a matrix and connecting the memory cells using a plurality of bit lines 1 and word lines 8. A data writing operation is performed in the MRAM using a spin torque injection method.

The semiconductor substrate 2 has the diffusion regions 3 and 4 on an upper surface thereof, and the diffusion region 3 is at a prescribed distance from the diffusion region 4. The diffusion region 3 acts as a drain region and the diffusion region 4 acts as a source region. The diffusion region 3 is connected to the MTJ device 10 through a contact plug 7.

The bit line 1 is disposed on the semiconductor substrate 2 and connected to the MTJ device 10 simultaneously. The bit line 1 is connected to a writing circuit and a reading circuit.

The diffusion region 4 is connected to the source line 6 through a contact plug 5. The source line 6 is connected to a writing circuit and a reading circuit.

A word line 8 is disposed on the semiconductor substrate 2 through a gate insulating layer 9, in order to be connected to the diffusion regions 3 and 4. The word line 8 and the gate insulating layer 9 act as a selection transistor. The word line 8 is activated by receiving a current from a circuit and the selection transistor is turned on.

As illustrated in FIG. 2, the MTJ device 10 has a stack structure of a fixed layer 13, a spacer layer 12, and a memory layer 11 in this order. The fixed layer 13 includes a ferromagnetic metal, e.g., iron (Fe), nickel (Ni), or CoFeB. The fixed layer 13 maintains a predetermined magnetization direction, which, for example, may be a direction perpendicular to a film surface or a longitudinal direction in a film surface. The fixed layer 13 may be referred to, for example, as a magnetization locked layer, a magnetization locked layer, a reference layer, magnetization reference layer, a pinned layer, a standard layer, or a magnetization standard layer.

The spacer layer 12 may include an insulator and act as a tunnel barrier layer. The insulator may be, for example, MgO or Al₂O₃. The thickness of the spacer layer 12 may be changed, for example, according to a resistance value of the MTJ device 10. Furthermore, at least one of the memory layer 11 or the fixed layer 13 may be epitaxially grown on the spacer layer 12 when the spacer layer 12 includes MgO.

The memory layer 11 includes a ferromagnetic insulating layer including a ferromagnetic insulator, e.g., a ferromagnetic oxide. The ferromagnetic oxide may include, for example, CoxFe_{3-X}O₄ (0<x<3) or BaFe₁₂O₁₉. CoxFe_{3-X}O₄ may be used for certain applications, for example, for having a higher magnetic anisotropy than 5×10⁵ J/m³ (=5×10⁶ erg/cc). CoFe₂O₄ (at x=1) may be an example of CoxFe_{3-X}O₄. For some applications, x may be 0.5 or more and CoxFe_{3-X}O₄ may have a spinel crystal structure. Furthermore, BaFe₁₂O₁₉ having a hexagonal crystal structure may be used.

The memory layer 11 has a variable magnetization direction. For example, the memory layer 11 is magnetized in a direction perpendicular to the film surface and faces upward or downward. The memory layer 11 may be referred to, for example, as a free layer, a magnetization free layer, or a magnetization variable layer. The thickness of the memory layer 11 may be changed, for example, according to a target device resistance value RA of the MTJ device 10.

A data writing operation for the memory cell 100 may be performed as follows. One of the memory cells 100 is selected from among a plurality of the memory cells 100 as an object in which data is written. The word line 8 is activated in the selected memory cell 100 and turned on by a selection transistor. The memory cell 100 receives writing current from a writing circuit according to the data to be written. For example, when a current flows in the bit line 1, the current flows to the MTJ device 10. Then, the temperature of the memory layer 11 increases and magnetic anisotropy of the same is reduced, because the memory layer 11 has insulating property.

As a result, a state is reached where it is easy to reverse the magnetization direction of the memory layer 11. Furthermore, the magnetization direction of the memory layer 11 is changed to a predetermined direction due to spin injection in the memory layer 11 by the current flowing into the MTJ device 10. Therefore, it is possible to write, for example, data corresponding to data 0 or data 1 in the memory cell 100.

A data reading operation from the memory cell 100 will now be described. One of the memory cells 100 is selected from among a plurality of the memory cells 100 as an object from which data is read. The word line 8 is activated in the selected memory cell 100 and turned on by a selection transistor. The memory cell 100 receives a reading current from a reading circuit according to the data to be read. The reading circuit detects a resistance value according to the reading current. Data stored in the memory cell 100 may be read according to the resistance value. Furthermore, when the memory layer 11 includes a ferromagnetic insulating layer including a ferromagnetic insulating oxide, such as CoxFe_{3-X}O₄, having a higher magnetic anisotropy, the memory layer 11 has high heat stability to magnetization during the data reading operation.

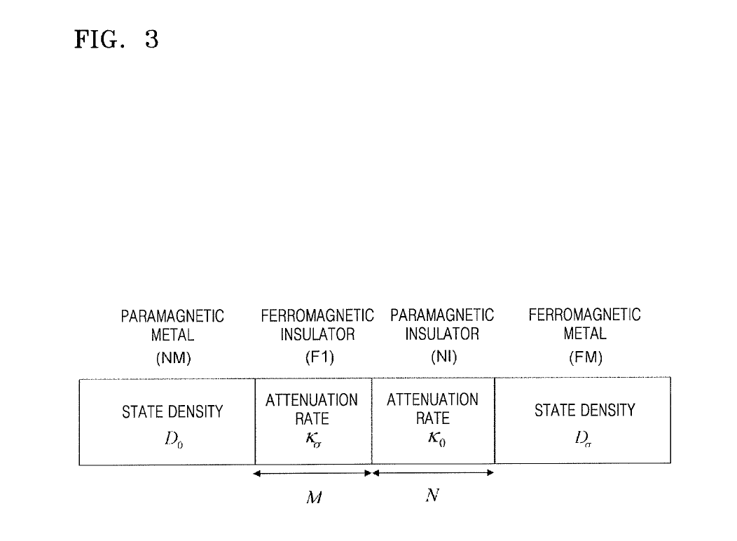

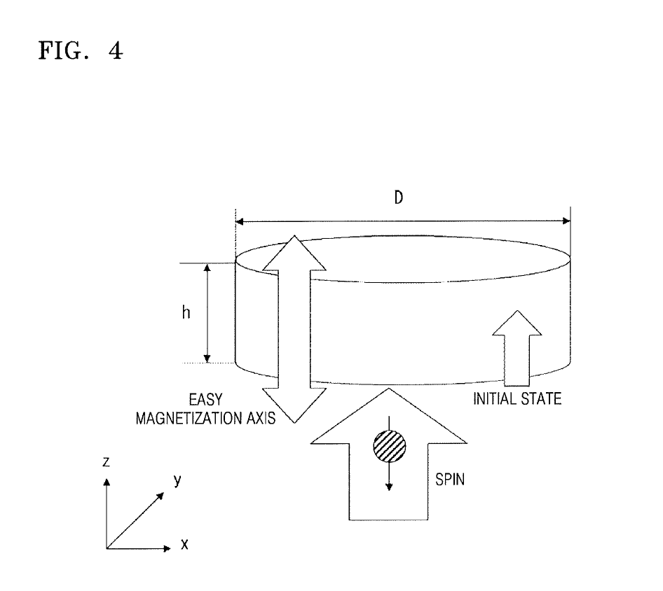

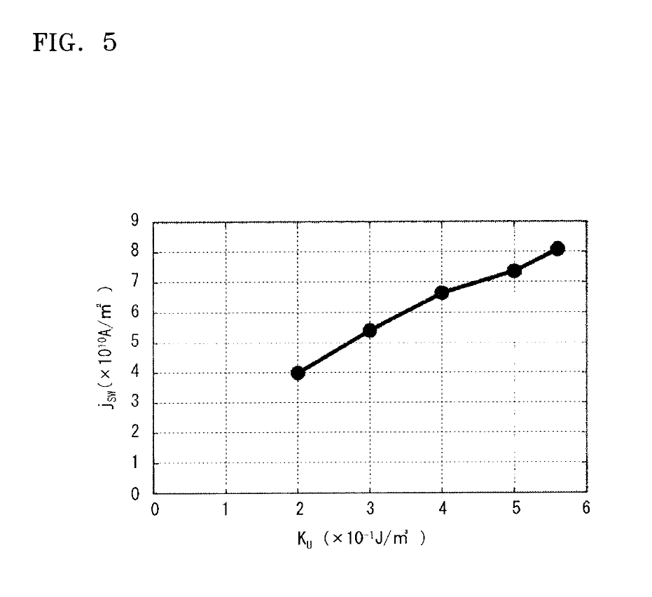

FIGS. 3 to 4 illustrate an example corresponding to a calculation result of an MRAM. In particular, FIGS. 3 and 4 illustrate an embodiment of a calculation model, and FIG. 5 illustrates an example of reverse current density corresponding to a magnetic anisotropy constant. In this embodiment, current density during magnetization reversal (in a data writing operation) is calculated when the MRAM has a predetermined magneto-resistance (MR) ratio.

As illustrated in FIG. 3, the calculation is performed using a tight binding model, according to a quantum mechanics. The tight binding model is a one-dimensional single track. Furthermore, a paramagnetic metal (NM) corresponds to a bit line 1 in the MTJ device 10. Similarly, a ferromagnetic insulator (FI) corresponds to the memory layer 11, a paramagnetic insulator (NI) corresponds to the spacer layer 12, and a ferromagnetic metal (FM) corresponds to the fixed layer 13.

First, an MR ratio MR is obtained using Equations 1 to 3.

MR=P_{I}P_{D}/(1−P₁P_{D}) (1)
MR[dimensionless]: MR ratio
PI[dimensionless]: spin polarizability of a spin filter effect in the ferromagnetic insulator (FI)
PD[dimensionless]: spin polarizability of an electronic state density in the ferromagnetic metal (FM)

P_{I}=(e^{-2κ}^{₊}^{M}−e^{-2κM})/(e^{-2κ}^{₊}^{M}+e^{-2κ}^{_{−}}^{M}) (2)
K₊[1/m]: attenuation rate of a wave function of a majority of spin electrons in the ferromagnetic insulator (FI)
K₋[1/m]: attenuation rate of a wave function of a minority of spin electrons in the ferromagnetic insulator (FI)
M[m]: film thickness of the ferromagnetic insulator (FI)

P_{D}=(D₊−D₋)/(D₊+D₋) (3)
D₊[1/J]: electronic state density of a majority of spin electrons in the ferromagnetic metal (FM)
D₋[1/J]: electronic state density of a minority of spin electrons in the ferromagnetic metal (FM)

If P₁ is 1, the MR ratio is represented as Equation 4.

MR=P_{D}/(1−PD) (4)

Furthermore, if P_{D} is 0.50 (50%), MR is converged to 1 (100%). That is, an MR ratio of the MTJ device 10 is high enough as 100%. Furthermore, it is possible to use symmetry of heat stability Δ in an interface of the paramagnetic insulator (NI) and the ferromagnetic metal (FM) when the paramagnetic insulator (NI) includes MgO and the ferromagnetic metal (FM) includes Fe.

The temperature T of the MTJ device 10 may be assumed to increase by a predetermined amount, e.g., about 200° C. using the MRAM.

Next, magnetization reversal current density is calculated based on the assumption that a value of the memory layer 11 is reduced until a value by which a magnetic anisotropy constant Kᵤ can operate as the MRAM by the temperature increasing. In this calculation, a model of FIG. 4 is used as a model of the ferromagnetic insulator (FI). The used model is a single-layer and a columnar body having a height h[nm] and a diameter D[nm]. In this model, the ferromagnetic insulator (FI) has an easy magnetization axis in a vertical direction and faces upward in an initial state.

Furthermore, the ferromagnetic insulator (FI) has a magnetic moment M_{S}[A/m] and a saturation magnetization per unit interface area A[J/m]. The height h, the diameter D, the magnetic moment M_{S}, the saturation magnetization per unit interface area A, a damping constant a, and the magnetic anisotropy constant Kᵤ are respectively set to the following values and calculated.
h=2 nm

D=20 nm
Ms=600×10³ A/m (=600 emu/cm³)
A=1×10⁻¹¹ J/m (=1μ erg/cm)
a=0.01
Kᵤ: determined by the heat stability Δ

The heat stability Δ is obtained using Equation 5.

Δ=KᵤV/k_{B}T (5)
Kᵤ[J/m³]: magnetic anisotropy constant of the memory layer
V[m³]: volume of the ferromagnetic insulator (FI)
k_{B}[J/K]: the Boltzmann constant
T[K]: temperature of the ferromagnetic insulator (FI)

As illustrated in FIG. 5, when the magnetic anisotropy constant Kᵤ is reduced, magnetization reversal current density j_{sw} is also reduced by the calculation result. For example, when the magnetic anisotropy constant Kᵤ is reduced from about 0.56 J/m³ (=about 5.6×10⁶ erg/cm³) to about 0.20 J/m³ (=about 2.0×10⁶ erg/cm³), the magnetization reversal current density j_{sw} is reduced from 8.1×10¹⁰ A/m² to 4.0×10¹⁰ A/m². That is, the magnetization reversal current density j_{sw} is reduced to 51%.

It is considered that current hardly flows into the MTJ device 10 during a data reading operation of the memory cell 100 when a calculation by classical electromagnetism is performed. Therefore, it may be believed that the MRAM including the MTJ device 10 does not operate. However, if a calculation according to the quantum mechanics is performed, it may be proved that the MRAM including the MTJ device 10 operates by the current flowing into the MTJ device 10, even during the data reading operation. An example of the calculation according to quantum mechanics will be described with reference to FIG. 3.

The transmission coefficient C of the MTJ device 10 is obtained using Equation 6. In this case, it may be assumed that κ₀N, κ_{σ}M>>1. In Equation 6, it may be confirmed that the transmission coefficient C of the MTJ device 10 exceeds a predetermined value by substituting a representative value and calculating the same. That is, it is confirmed that an electron with respect to the MTJ device 10 in the memory cell 100 of the MRAM passes through at least one of the fixed layer and the memory layer including an insulating layer during the data reading operation. Therefore, the MRAM including the MTJ device 10 may be operated, because the MTJ device 10 may allow current to flow during the data reading operation.

C≈4π²t²e^{-2κ}^{₀}^{N}e^{-2κ}^{_{σ}}^{M}D₀D_{σ′} (6)
C[dimensionless]: transmission coefficient
t[J]: hopping integral of electrons
κ_{σ}[1/m]: attenuation rate of a wave function of c spin electrons in the ferromagnetic insulator (FI)
N[m]: film thickness of the paramagnetic insulator (NI)
M[m]: film thickness of the ferromagnetic insulator (FI)
κ₀[1/m]: attenuation rate of a wave function of an electron in the paramagnetic insulator (NI)
D_{σ′}[1/J]: electronic state density of G′ spin electrons in the ferromagnetic metal (FM)
D₀[1/J]: electronic state density of the paramagnetic metal (NM)

According to the MRAM of this exemplary embodiment, the temperature of the memory layer increases, the magnetic anisotropy constant of the memory layer is reduced, and magnetization reversal current density is also reduced during the magnetization reversal of the memory layer including the ferromagnetic insulator. Thus, it is possible to perform the magnetization reversal of the memory layer by a low current density using the memory layer including the ferromagnetic insulator. For example, the MTJ device using a memory layer including the ferromagnetic insulator has a relatively high MR ratio (a magnetroresistance effect) and low magnetization reversal current density. Furthermore, power consumption of the MRAM having the MTJ device is low.

For some applications, a device resistance value RA of the MTJ device 10 may be 30 Ωμm² or less. The device resistance value RA may be changed by changing thicknesses of the spacer layer 12 and the memory layer 11. The MTJ device may demonstrate excellent data reading performance when the device resistance value RA of the MTJ device 10 is 30 Ωμm² or less. However, the MTJ device may use different device resistance values in other embodiments. The MRAM having the MTJ device may also have a large storage capacity.

Furthermore, in one embodiment, a layer including a ferromagnetic insulator may be used as the memory layer in the MRAM. For example, the MRAM may use various materials having a perpendicular magnetic anisotropy.

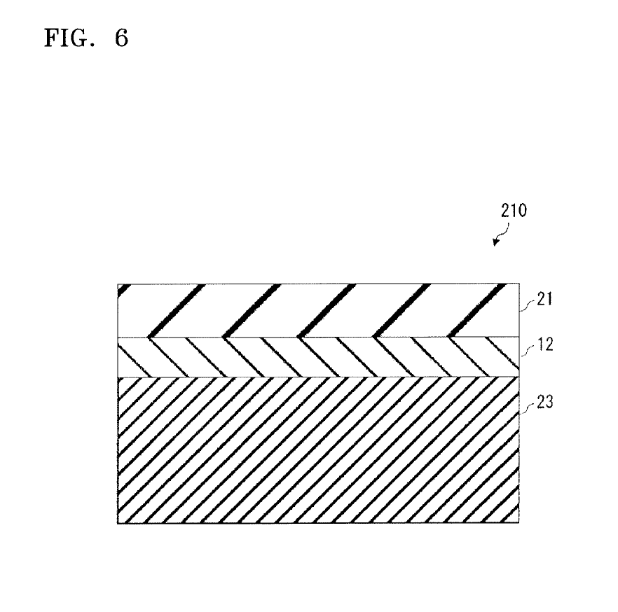

FIG. 6 illustrates a sectional view of another embodiment of an MTJ device 210. In this embodiment, the memory layer is different compared to the MTJ device 10 in FIG. 2. As illustrated in FIG. 6, the MTJ device 210 has a stack structure of a fixed layer 23, a spacer layer 12, and a memory layer 21 in this order. The memory layer 21 includes a ferromagnetic metal as well as the fixed layer 13 of FIG. 2. The ferromagnetic metal may be, for example, Fe or CoFeB. The memory layer 21 has a variable magnetization direction, e.g., the memory layer 21 may be magnetized in a direction perpendicular to a film surface.

The fixed layer 23 includes a ferromagnetic insulating layer, which, for example, may include the same ferromagnetic insulating material as the memory layer 11 of FIG. 2. The fixed layer 23 maintains a magnetization direction perpendicular to the film surface. The thickness of the fixed layer 23 may be properly changed according to the resistance value of the MTJ device 210.

Furthermore, magnetic division in a conduction band of the fixed layer 23 occurs and a tunneling probability changes according to spin directions of conduction electrons. Therefore, a spin filter effect may occur, e.g., an effect where more electrons having a spin parallel (or anti-parallel) to a magnetization direction of the fixed layer 23 pass through the fixed layer 23. A spin polarizability of the spin filter effect may be changed by changing the thickness of the fixed layer 23.

In a data reading operation, reading current flows from the fixed layer 23 to the memory layer 21. More electrons having a spin parallel (or anti-parallel) to the magnetization direction of the fixed layer 23 flow into the fixed layer 23. Thus, the spin filter effect is provided, and the higher the spin polarizability, the higher the MR ratio. As the MR ratio increases, a signal voltage from the MTJ device 210 also increases. As a result, the MTJ device 210 demonstrates excellent data reading performance. In addition, an MRAM using the MTJ device 210 has a large storage capacity. Furthermore, when the fixed layer 23 includes a ferromagnetic insulating layer including a ferromagnetic insulating oxide, such as CoxFe_{3-X}O₄, having a higher magnetic anisotropy, the memory layer 21 has high heat stability to magnetization during the data reading operation.

In data writing operation, when a writing current flows into the bit line 1, writing current flows into the MTJ device 210. Then, the temperature of the fixed layer 23 increases. The temperature of the memory layer 21 may also increase because the fixed layer 23 has insulating properties. Therefore, a state is reached where it is easy to reduce magnetic anisotropy and reverse a magnetization direction of the memory layer 21. Furthermore, the magnetization direction of the memory layer 21 is changed to a predetermined direction due to spin-torque transmission in the memory layer 21 by the current flowing into the MTJ device 210. Therefore, it is possible to write data corresponding, for example, to data 0 or data 1, in the memory cell 100. Also, in the MTJ device 210, it is possible to reverse the magnetization direction by a low current density as well as the MTJ device 10. Furthermore, the MRAM including the MTJ device 210 has low power consumption.

According to another embodiment, the MTJ device may have low magnetization reversal current density. Furthermore, the MTJ device may have a high MR ratio and excellent data reading performance. Moreover, the MTJ device may have low power consumption and may form an MRAM having a large storage capacity.

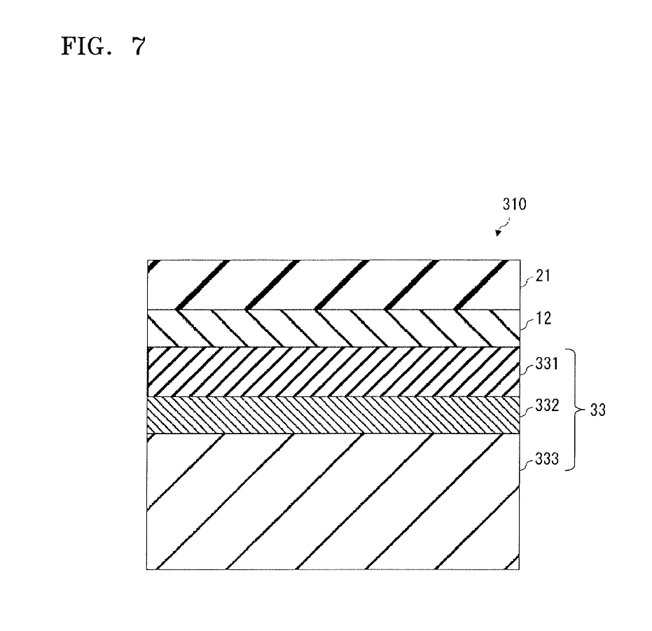

FIG. 7 illustrates a sectional view of another embodiment of an MTJ device 310. This embodiment may be the same as the MTJ device 210 of FIG. 6 except for the fixed layer. As illustrated in FIG. 7, An MTJ device 310 has a stack structure of a fixed layer 33, a spacer layer 12, and a memory layer 21 in this order.

The fixed layer 33 has a stack structure of a perpendicular magnetization holding layer 333, a magnetic coupling control layer 332, and a ferromagnetic layer 331 in this order. The ferromagnetic layer 331 includes a ferromagnetic insulating layer including the same ferromagnetic insulating material as the memory layer 11 of FIG. 2. The ferromagnetic layer 331 has a perpendicular magnetic anisotropy constant Kᵤ₁. Furthermore, the ferromagnetic insulator may not maintain a magnetization direction perpendicular to a film surface, unlike the ferromagnetic insulator forming the fixed layer 23 of FIG. 6.

The magnetic coupling control layer 332 includes a material having an influence on magnetic coupling of the ferromagnetic layer 331 and the perpendicular magnetization holding layer 333. The material may be, for example, Rh, Pd, Pt, Ru, or MgO. The thickness of the magnetic coupling control layer 332 may be, for example, 2 nm or less. The thickness may be different in another embodiment. Changing the thickness of the magnetic coupling control layer 332 may produce a change in, for example, MR ratio (a resistance changing rate), heat stability, a recording current, a magnetization reversal speed, and/or another factor.

The perpendicular magnetization holding layer 333 includes a material having a perpendicular magnetic anisotropy constant Kᵤ₂. The perpendicular magnetic anisotropy constant Kᵤ₂ is higher than the perpendicular magnetic anisotropy constant Kᵤ₁ of the ferromagnetic layer 331. The material may be, for example, Fe, Pd or FePt of L10 type.

The MTJ device 310 also includes the magnetic coupling control layer 332 in the fixed layer 33. However, the magnetic coupling control layer 332 may be excluded from the fixed layer 33. For example, the MTJ device 310 may include a fixed layer laminating the perpendicular magnetization holding layer 333 and the ferromagnetic layer 331 in this order, instead of the fixed layer 33.

In a data reading operation, reading current flows from the fixed layer 33 to the memory layer 21. More electrons having a spin parallel (or anti-parallel) to the magnetization direction of the fixed layer 33 flow into the fixed layer 33. Thus, a spin filter effect is provided, and the higher the spin polarizability, the higher the MR ratio. As the MR ratio increases, a signal voltage from the MTJ device 310 also increases. Thus, the MTJ device 310 may have excellent data reading performance. An MRAM using the MTJ device 310 may have a large storage capacity. Furthermore, when the ferromagnetic layer 331 includes a ferromagnetic insulating layer including a ferromagnetic insulating oxide, such as CoxFe_{3-X}O₄, having a higher magnetic anisotropy, the memory layer 21 has high heat stability to magnetization during the data reading operation.

In a data writing operation, when writing current flows into the bit line 1, the writing current flows into the MTJ device 310. Then, the temperature of the fixed layer 33 increases. The temperature of the memory layer 21 may also increase because the fixed layer 33 has insulating properties. Therefore, a state is reached where it is easy to reduce magnetic anisotropy and reverse a magnetization direction of the memory layer 21. Furthermore, the magnetization direction of the memory layer 21 is changed to a predetermined direction due to spin-torque transmission in the memory layer 21 by the current flowing into the MTJ device 310. Therefore, it is possible to write, for example, data corresponding to data 0 or data 1 in the memory cell 100. In the MTJ device 310, it is also possible to reverse the magnetization direction by a low current density, as well as in the MTJ device 210.

In this and the previous embodiment, the MTJ device may have low magnetization reversal current density. Furthermore, the MTJ device may have a high MR ratio and excellent data reading performance. Moreover, the MTJ device may form a MRAM having a large storage capacity. Furthermore, in this embodiment, it may be possible to adjust MR ratio (a resistance changing rate), heat stability, recording current, magnetization reversal speed, and/or another factor by adjusting the thickness of the magnetic coupling control layer 332.

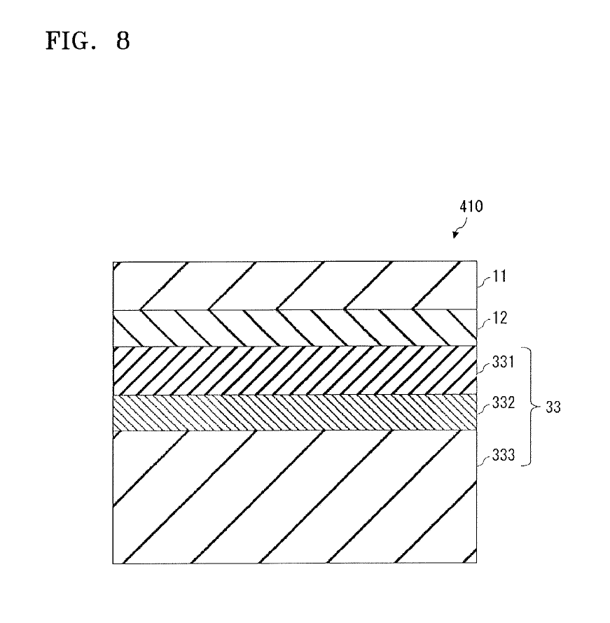

FIG. 8 illustrates a sectional view of another embodiment of an MTJ device 410. This embodiment may be the same as the MTJ device 10 of FIG. 2 except for the fixed layer. As illustrated in FIG. 8, a MTJ device 410 has a stack structure of a memory layer 11, a spacer layer 12, and a fixed layer 33 in this order. The fixed layer 33 is the same configuration as the MTJ device 310 of FIG. 7.

In a data writing operation, a memory cell using the MTJ device 410 receives a writing current from a writing circuit according to written data. For example, when the writing current flows into the bit line 1, the writing current flows into the MTJ device 410. Then, a magnetization direction of the memory layer 11 is changed to a predetermined direction as well as the MTJ device 10 of FIG. 2 according to one or more previous embodiments. Therefore, it may be possible to write, for example, data corresponding to data 0 or data 1 in the memory cell 100. The MTJ device 410 may have low magnetization reversal current density. An MRAM including the MTJ device ma have low power consumption.

In a data reading operation, reading current flows from the fixed layer 33 to the memory layer 11. More electrons having a spin parallel (or anti-parallel) to the magnetization direction of the fixed layer 33 flow into the fixed layer 33. Thus, a spin filter effect is provided, and the higher the spin polarizability, the higher the MR ratio. As the MR ratio increases, a signal voltage from the MTJ device 410 also increases. Thus, the MTJ device 410 has excellent data reading performance. Also, an MRAM using the MTJ device 410 may have a large storage capacity. Furthermore, when the ferromagnetic layer 331 includes a ferromagnetic insulating layer including a ferromagnetic insulating oxide, such as CoxFe_{3-X}O₄, having a higher magnetic anisotropy, the memory layer 11 may have high heat stability to magnetization during the data reading operation.

In this embodiment, the MTJ device may reverse the magnetization direction of the memory layer 11 even by a low current density. Furthermore, the MTJ device has a high MR ratio, and thus may have excellent data reading performance. Moreover, the MRAM including the MTJ device may reverse the power consumption.

In another embodiment, the MTJ device according to any of the aforementioned embodiments include a memory layer laminating a perpendicular magnetization holding layer and a ferromagnetic layer, instead of the memory layer. Furthermore, the MTJ device 210 of FIG. 6 may include a memory layer including a ferromagnetic insulator instead of the memory layer 21.

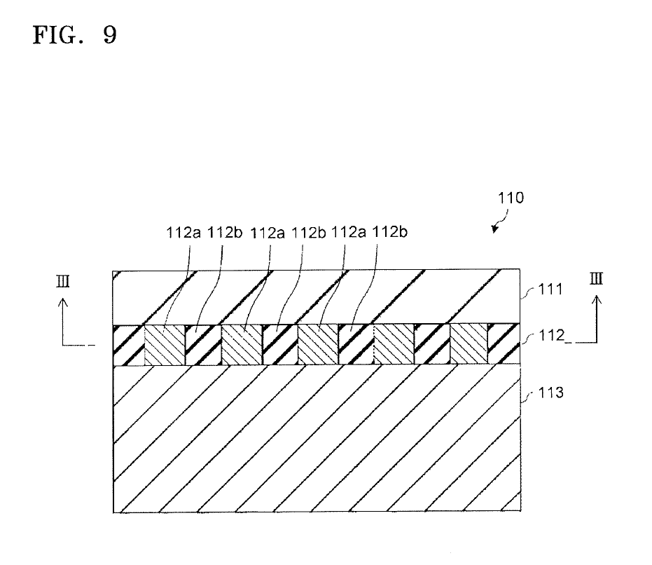

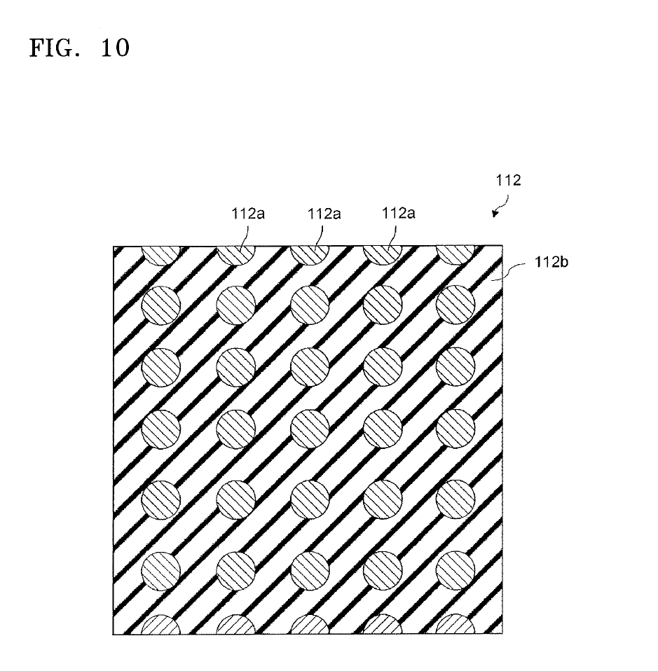

FIGS. 9 and 10 illustrate another embodiment of an MTJ device 110. In particular, FIG. 9 illustrates a sectional view of the MTJ device and FIG. 10 illustrates a sectional view of a main part of the MTJ device.

As illustrated in FIGS. 9 and 10, the MTJ device 110 has a stack structure of a fixed layer 113, a spacer layer 112, and a memory layer 111 in this order. The MTJ device 110 changes the magnetization direction of the memory layer 111 using a spin torque injection method during a data writing operation. Furthermore, electrons tunnel through the fixed layer 113, the spacer layer 112, and the memory layer 111 of the MTJ device 110 during a data reading operation, and current may flow at different voltages according to the magnetization direction of the memory layer 111.

In this embodiment, the magnetization direction of the memory layer may change using a spin torque injection method during a data writing operation. Also, current may flow with different voltages according to the magnetization direction of the memory layer by tunneling a layer including an insulator by electrons during a data reading operation. Thus, this embodiment may include a stacked configuration of a fixed layer including a ferromagnetic metal, a tunnel barrier layer including an insulator, and a memory layer including a ferromagnetic metal.

The fixed layer 113 includes a ferromagnetic metal, e.g., Fe, Ni, or CoFeB. The fixed layer 113 maintains a predetermined magnetization direction, e.g., a direction perpendicular to a film surface or a longitudinal direction in the film surface. Furthermore, the fixed layer 113 may be referred to as a magnetization locked layer, a magnetization locked layer, a reference layer, a magnetization reference layer, a pinned layer, a standard layer, or a magnetization standard layer.

The spacer layer 112 includes current paths 112a electrically connecting the memory layer 111 and the fixed layer 113, and an insulator electrically insulating the memory layer 111 and the fixed layer 113. The spacer layer 112 includes, for example, matrixes 112b respectively surrounding the current paths 112a. The matrixes 112b include a non-magnetic insulator, e.g., MgO, or Al₂O₃. The current paths 112a may be columnar bodies including a non-magnetic metal, e.g., a paramagnetic metal. The paramagnetic metal may be, for example, Cu, Ag, Al, or their alloys. The current paths 112a may also be arranged in the matrixes 112b and may pass through the matrixes 112b.

The spacer layer 112 may have a thickness based on, for example, a resistance value of the MTJ device 110. Furthermore, the spacer layer 112 may have current paths 112a including Cu and matrixes 112b including Al₂O₃. In this case, the spacer layer 112 may be obtained, for example, by forming a film including AlCu and oxidizing only Al by performing an oxidation process. The oxidation process may use natural oxidation (NO) and ion-assisted oxidation (IAO). Furthermore, a magnetoresistance ratio of the MTJ device 110 may increase due to current constriction, which occurs when current passes through the spacer layer 112.

The memory layer 111 includes a ferromagnetic insulating layer including a ferromagnetic insulator, e.g., a ferromagnetic oxide. The ferromagnetic oxide may include, for example, CoₓFe_{3-X}O₄ (e.g., 0<x<3) or BaFe₁₂O₁₉. For some applications, CoxFe_{3-X}O₄ may be more suitable as the ferromagnetic oxide with a magnetic anisotropy higher than 5×10⁵ J/m³ (=5×10⁶ erg/cc). For example, CoxFe_{3-X}O₄ may be CoFe₂O₄ (at x=1). In one embodiment, x may be 0.5 or more and CoxFe_{3-X}O₄ may have a spinel crystal structure.

Moreover, BaFe₁₂O₁₉ may have a hexagonal crystal structure in some embodiments. The memory layer 111 may have a variable magnetization direction. For example, the memory layer 111 is magnetized in a direction perpendicular to the film surface and faces upward or downward. The memory layer 11 may be referred to as a free layer, a magnetization free layer, or a magnetization variable layer. The thickness of the memory layer 11 may be changed, for example, according to a target device resistance value RA of the MTJ device 110.

The current may be considered to hardly flow into the MTJ device 110 during a data reading operation, when a calculation is performed by classical electromagnetism. Under this scenario, it may be understood that the MRAM including the MTJ device 110 does not operate. However, if a calculation according to quantum mechanics is performed, it may be proved that the MRAM including the MTJ device 110 operates based on current flowing into the MTJ device 110, even during a data reading operation.

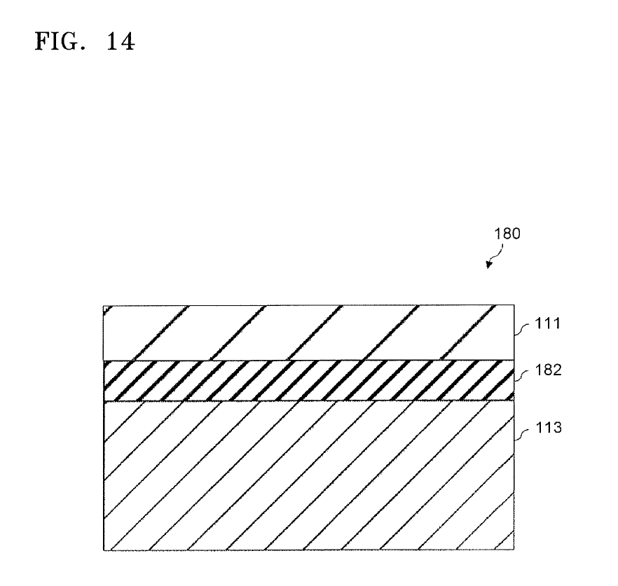

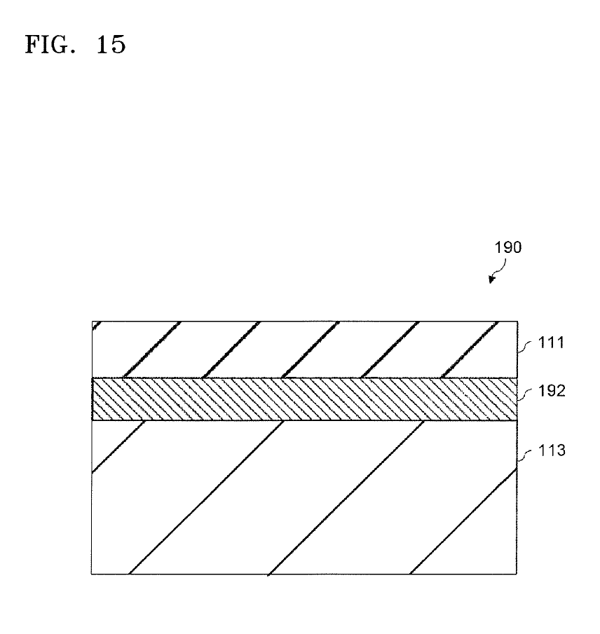

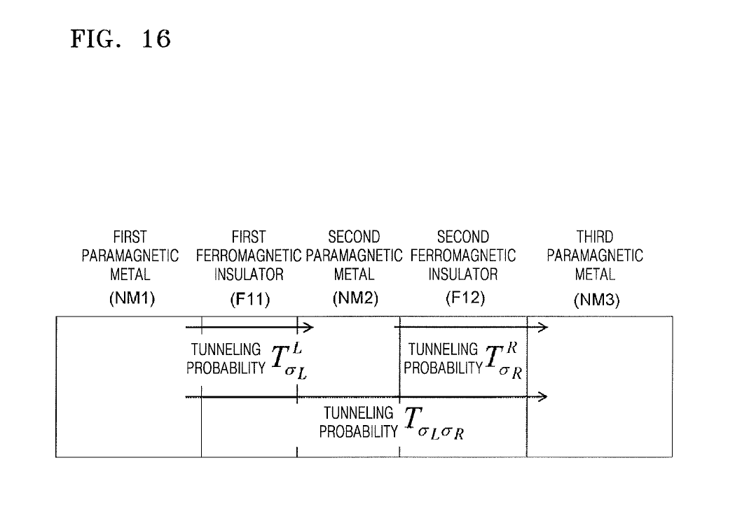

For example, an MTJ device according to the following Reference examples 1 and 2 is proved based on calculations according to quantum mechanics. The proof based on the quantum mechanics calculations will be described with reference to FIG. 3 and FIGS. 14 to 16. FIGS. 14 and 15 are sectional views of the MTJ device according to Reference example 1. FIGS. 3 and 16 are views of a calculation model.

### Reference Example 1

FIGS. 3 and 14 illustrate an example of a calculation result of an MRAM according to Reference example 1. As illustrated in FIG. 14, a MTJ device 180 has the same configuration as the MTJ device 110 of FIG. 9, except for a spacer layer 182. The spacer layer 182 includes a paramagnetic insulator. The MTJ device 180 is used as a configuration factor of the MRAM by being installed in the memory cell 100 of FIG. 1, as well as the MTJ device 110.

As illustrated in FIG. 3, the calculation is performed using a tight binding model according to quantum mechanics. The tight binding model is a one-dimensional single track. Furthermore, a paramagnetic metal (NM) corresponds to a bit line 1 of the memory cell 100. A ferromagnetic insulator (FI) corresponds to the memory layer 111, a paramagnetic insulator (NI) corresponds to the spacer layer 182, and a ferromagnetic metal (FM) corresponds to the fixed layer 113.

The transmission coefficient C of the MTJ device 180 is obtained using Equation 7. In this case, it is assumed that κ₀N, κ_{σ}>>1. It may be believed that current flows into the MTJ device 180 as the transmission coefficient C of the MTJ device 180 exceeds a predetermined value. That is, it may be confirmed that an electron with respect to the MTJ device 180 in the memory cell 100 of the MRAM passes through the fixed layer and the memory layer including an insulating layer during a data reading operation. Therefore, the MRAM including the MTJ device 180 may operate as the MTJ device 180 allows current to flow during the data reading operation.

C≈4π²t²e^{-2κ}^{₀}^{N}e^{-2κ}^{_{σ}}^{M}D₀D_{σ′} (7)
C[dimensionless]: transmission coefficient
t[J]: hopping integral of electrons
κ_{σ}[1/m]: attenuation rate of a wave function of σ spin electrons in the ferromagnetic insulator (FI)
N[m]: film thickness of the paramagnetic insulator (NI)
M[m]: film thickness of the ferromagnetic insulator (FI)
κ₀[1/m]: attenuation rate of a wave function of an electron in the paramagnetic insulator (NI)
D_{σ′}[1/J]: electronic state density of σ′ spin electrons in the ferromagnetic metal (FM)
D₀[1/J]: electronic state density of the paramagnetic metal (NM)

### Reference Example 2

FIGS. 15 and 16 illustrate a calculation result of an MRAM according to Reference example 2. As illustrated in FIG. 15, a MTJ device 190 has the same configuration as the MTJ device 110 of FIG. 9, except for a spacer layer 192 and a fixed layer 193. The spacer layer 192 includes a paramagnetic metal and the fixed layer 193 includes a ferromagnetic insulator. The MTJ device 190 is used as a configuration factor of the MRAM by being installed in the memory cell 100 of FIG. 1, as well as the MTJ device 110.

As illustrated in FIG. 16, the calculation is performed using a tight binding model according to quantum mechanics. The tight binding model is a one-dimensional single track. Furthermore, a first paramagnetic metal (NM1) corresponds to the bit line 1 of FIG. 1 of the memory cell 100. Similarly, a first ferromagnetic insulator (FI1) corresponds to the memory layer 111 and a second paramagnetic metal (NM2) corresponds to the spacer layer 192. Furthermore, a second ferromagnetic insulator (FI2) corresponds to the fixed layer 193 and a third paramagnetic metal (NM3) corresponds to the contact plug 7 (of FIG. 1).

First, tunneling probabilities of the first ferromagnetic insulator (FI1), the second paramagnetic metal (NM2), and the second ferromagnetic insulator (FI2) are obtained. It may be assumed that the tunneling probabilities of the first ferromagnetic insulator (FI1) and the second ferromagnetic insulator (FI2) are both much lower than 1, in accordance with Equation 8.

T₊^{L},T₋^{L},T₊^{R},T₋^{R},<<1 (8)
T₊^{L}: tunneling probability of a first ferromagnetic insulator (FI1) corresponding to a majority of spin (+) electrons
T₋^{L}: tunneling probability of a first ferromagnetic insulator (FI1) corresponding to a majority of spin (−) electrons
T₊^{R}: tunneling probability of a second ferromagnetic insulator (FI2) corresponding to a majority of spin (+) electrons
T₋^{R}: tunneling probability of a second ferromagnetic insulator (FI2) corresponding to a majority of spin (−) electrons

The tunneling probabilities are improved when energy of electrons incident from the first paramagnetic metal (NM1) or the third paramagnetic metal (NM3) conforms to an energy level in the second paramagnetic metal (NM2). When such a resonance condition is satisfied, a tunneling probability of a junction (MTJ90) including the first ferromagnetic insulator (FI1), the second paramagnetic metal (NM2), and the second ferromagnetic insulator (FI2) may be described based on Equation 9.

$${T}_{{σ}_{L} {σ}_{R}} \approx \frac{4 {T}_{{σ}_{L}}^{L} {T}_{{σ}_{R}}^{R}}{{( {T}_{{σ}_{L}}^{L} + {T}_{{σ}_{R}}^{R} )}^{2}} \\ resonance condition \qquad ( 9 )$$

T_{σ}_{_{L}}_{σ}_{_{R}}: tunneling probability of junction (in MTJ90) including the first ferromagnetic insulator (FI1), the second paramagnetic metal (NM2), and the second ferromagnetic insulator (FI2)
T_{σ}_{_{L}}^{L}: tunneling probability of the first ferromagnetic insulator (FI1)
T_{σ}_{_{R}}^{R}: tunneling probability of the second ferromagnetic insulator (FI2)

The tunneling probability of the junction (MTJ90) including the first ferromagnetic insulator (FI1), the second paramagnetic metal (NM2), and the second ferromagnetic insulator (FI2) may be described based on Equation 10 below a non-resonance condition not satisfying the resonance condition.

$${T}_{{σ}_{L} {σ}_{R}} \approx \frac{{T}_{{σ}_{L}}^{L} {T}_{{σ}_{R}}^{R}}{4} \\ non \text{-} resonance condition \qquad ( 10 )$$

In Equations 9 and 10, by substituting a representative value and calculating the same, it may be confirmed that the tunneling probability of the junction (in MTJ 190) including the first ferromagnetic insulator (FI1), the second paramagnetic metal (NM2), and the second ferromagnetic insulator (FI2) exceeds 0 (zero). Thus, it is confirmed that an electron with respect to the MTJ device 110 in the memory cell 100 of the MRAM passes through the fixed layer and the memory layer including an insulating layer during a data reading operation. Therefore, the MRAM including the MTJ device 190 may operate as current in the MTJ device 190 flows during a data reading operation.

The probability of satisfying the resonance condition may be adjusted, so that the resonance condition is satisfied when magnetization directions of the first ferromagnetic insulator (FI1) and the second ferromagnetic insulator (FI2) are parallel. The resonance condition is not satisfied when magnetization directions of the first ferromagnetic insulator (FI1) and the second ferromagnetic insulator (FI2) are anti-parallel. These adjustments may be made, for example, by changing materials or sizes of the first paramagnetic metal (NM1), the first ferromagnetic insulator (FI1), the second paramagnetic metal (NM2), the second ferromagnetic insulator (FI2), and/or the third paramagnetic metal (NM3). Here, an MR ratio (magnetoresistance ratio) of the MTJ device 110 is obtained. The MR ratio of the MTJ device 110 may be represented based on Equation 11. Referring to Equation 7, the MR ratio may be approximately 100% (see Equation 12). That is, the MTJ device 10 may have a high MR ratio that is approximately 100%.

$$\begin{matrix}MR = \frac{\frac{16 {T}_{+}^{L} {T}_{+}^{R}}{{( {T}_{+}^{L} + {T}_{+}^{R} )}^{2}} + {T}_{-}^{L} {T}_{-}^{R} - {T}_{+}^{L} {T}_{-}^{R} - {T}_{-}^{L} {T}_{+}^{R}}{\frac{16 {T}_{+}^{L} {T}_{+}^{R}}{{( {T}_{+}^{L} + {T}_{+}^{R} )}^{2}} + {T}_{-}^{L} {T}_{-}^{R}} & ( 11 ) \\ MR \approx 100 \% & ( 12 )\end{matrix}$$

The MTJ device 10 of FIG. 1 may have the same configuration as the MTJ device 180 according to Reference example 1, except for the spacer layer. The spacer layer 112 of the MTJ device 110 has a higher conductivity than the spacer layer 182 including a paramagnetic insulator. Current flows more easily in the MTJ device 110 than in the MTJ device 180, because the MTJ device 110 has a configuration factor with higher conductivity than the MTJ device 180.

Furthermore, the MTJ device 110 has the same configuration as the MTJ device 190 according to Reference example 2, except for the spacer layer and the fixed layer. The spacer layer 112 of the MTJ device 110 has a lower conductivity than the spacer layer 192 including a paramagnetic metal. The fixed layer 113 has a higher conductivity than the fixed layer 193 including a ferromagnetic insulator. Current flowing in the MTJ device 110 may be the same level as in the MTJ device 190, because the MTJ device 110 has a configuration factor with the same level conductivity as the MTJ device 190.

As described above, both of the MTJ devices 180 and 190 allow current to flow during a data reading operation. Under one assumption, it may be understood that current flows in the MTJ device 110 at the same level as in the MTJ device 190, or flows more easily in the MTJ device 110 than in the MTJ device 180. Therefore, the MRAM including the MTJ device 110 may be operated.

The temperature T of the MTJ device 10 may increase about 200° C. using the MRAM.

Magnetization reversal current density is calculated based on the assumption that a value of the memory layer 111 is reduced until a value is reached where a magnetic anisotropy constant Kᵤ is operated as the MRAM as temperature increases. In this calculation, the model of FIG. 4 may be used as the model of the first ferromagnetic insulator (FI1). This model is a single-layer with a columnar body having a height h[nm] and a diameter D[nm]. In this model, the first ferromagnetic insulator (FI1) has a magnetization axis in a vertical direction and faces upward in an initial state. Furthermore, the first ferromagnetic insulator (FI1) has a magnetic moment M_{S}[A/m] and a saturation magnetization per unit interface area A[J/m]. The height h, the diameter D, the magnetic moment M_{S}, the saturation magnetization per unit interface area A, a damping constant a, and a magnetic anisotropy constant Kᵤ may be respectively set to the following values and calculated.
h=2 nm
D=20 nm
Ms=600×10³ A/m (=600 emu/cm³)
A=1×10⁻¹¹ J/m (=1 μerg/cm)
a=0.01
Kᵤ: determined by heat stability Δ

The heat stability A may be obtained based on Equation 13.

Δ=KᵤV/k_{B}T (13)
Ku[J/m³]: a magnetic anisotropy constant of the memory layer (first ferromagnetic insulator (FI1))
V[m³]: a volume of the first ferromagnetic insulator (FI1)
kb[J/K]: a Boltzmann constant
T[K]: a temperature of the first ferromagnetic insulator (FI1)

As illustrated in FIG. 5, when the magnetic anisotropy constant Kᵤ is reduced, magnetization reversal current density j_{sw} is also reduced in accordance with the calculation result. For example, when the magnetic anisotropy constant Kᵤ is reduced from about 0.56 J/m³ (=about 5.6×10⁶ erg/cm³) to about 0.20 J/m³ (=about 2.0×10⁶ erg/cm³), the magnetization reversal current density j_{sw} is reduced from 8.1×10¹⁰ A/m² to 4.0×10¹⁰ A/m². Thus, the magnetization reversal current density j_{sw}, is reduced to 51%.

In the MRAM according to one or more of the aforementioned embodiments, the temperature of the memory layer increases, the magnetic anisotropy constant of the memory layer is reduced, and magnetization reversal current density is also reduced during the magnetization reversal of the memory layer including the ferromagnetic insulator. Thus, it is possible to perform the magnetization reversal of the memory layer by a low current density using the memory layer including the ferromagnetic insulator. In other words, the MTJ device using the memory layer including the ferromagnetic insulator has a relatively high MR ratio (a magnetroresistance effect) and low magnetization reversal current density. Furthermore, power consumption of the MRAM having the MTJ device is low.

Also, the device resistance value RA of the MTJ device 110 may be 30 Ωμm² or less. In the MTJ device 110, the spacer layer 112 may include a paramagnetic metal between the fixed layer 113 and the memory layer 111. Therefore, the MTJ device 110 may be suppressed to a desirable device resistance value, compared to an MTJ device having a tunnel barrier layer that includes an insulator instead of the spacer layer 112. Furthermore, the device resistance value RA may be changed by changing an area of the current paths 112a in a section of the spacer layer 112 of FIG. 10 or thicknesses of the spacer layer 112 and the memory layer 111. The MTJ device 110 may have excellent data reading performance, especially when the device resistance value RA of the MTJ device 110 is 30 Ωμm² or less. Also, the MRAM having the MTJ device may have a large storage capacity.

A layer including a ferromagnetic insulator may be used as a memory layer according to the MRAM formed according to one or more of the aforementioned embodiments. The MRAM may use various materials having a perpendicular magnetic anisotropy.

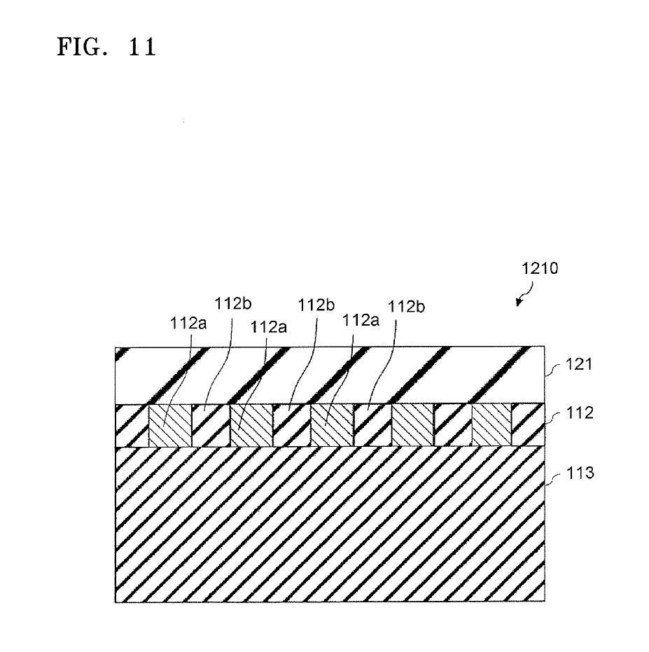

FIG. 11 illustrates a sectional view of an MTJ device according to another embodiment. In this embodiment, the memory layer is replaced with the fixed layer, and thus is different compared to the MTJ device 110 of FIG. 9.

As illustrated in FIG. 11, the MTJ device 1210 has a stack structure of a fixed layer 123, a spacer layer 112, and a memory layer 121 in this order. The memory layer 121 includes a ferromagnetic metal as well as the fixed layer 113 of FIG. 9. The ferromagnetic metal may be, for example, Fe, Ni or CoFeB. The memory layer 121 has a variable magnetization direction. For example, the memory layer 121 is magnetized in a direction perpendicular to a film surface.

The fixed layer 123 includes a ferromagnetic insulating layer including the same ferromagnetic insulator as the memory layer 111 of FIG. 9. The fixed layer 123 maintains a magnetization direction perpendicular to the film surface. The thickness of the fixed layer 123 may be changed based on the resistance value of the MTJ device 1210.

Furthermore, magnetic division in a conduction band of the fixed layer 123 occurs. Also, the tunneling probability changes according to spin directions of conduction electrons. Therefore, a spin filter occurs where more electrons having a spin parallel (or anti-parallel) to a magnetization direction of the fixed layer 123 pass through the fixed layer 123. A spin polarizability of the spin filter effect may be changed by changing the film thickness of the fixed layer 123.

In a data reading operation, reading current flows from the fixed layer 123 to the memory layer 121. More electrons having a spin parallel (or anti-parallel) to the magnetization direction of the fixed layer 123 flow into the fixed layer 123. Thus, the spin filter effect is provided, and the higher the spin polarizability, the higher the MR ratio. As the MR ratio increases, a signal voltage from the MTJ device 1210 also increases. Thus, the MTJ device 1210 may have excellent data reading performance. An MRAM using the MTJ device 1210 may have large storage capacity. Furthermore, when the fixed layer 123 includes a ferromagnetic insulating layer including a ferromagnetic insulating oxide, such as CoxFe_{3-X}O₄, having a higher magnetic anisotropy, the memory layer 121 may have high heat stability to magnetization during a data reading operation.

In data writing operation, when a writing current flows into the bit line 1, writing current flows into the MTJ device 1210. Then, the temperature of the fixed layer 123 increases. The temperature of the memory layer 121 may also increase because the fixed layer 123 has insulating properties. Therefore, a state may be reached where it is easy to reduce magnetic anisotropy and reverse a magnetization direction of the memory layer 121. Furthermore, the magnetization direction of the memory layer 121 is changed to a predetermined direction due to spin-torque transmission in the memory layer 121 by the current flowing into the MTJ device 1210. Therefore, it is possible to write data corresponding, for example, to data 0 or data 1, in the memory cell 100. Thus, it is possible to reverse the magnetization direction by a low current density, as well as in the MTJ device 110. Furthermore, the MRAM including the MTJ device 1210 has low power consumption.

In this embodiment, the MTJ device may have low magnetization reversal current density. Furthermore, the MTJ device has a high MR ratio and excellent data reading performance. Moreover, the MTJ device has low power consumption and may form an MRAM having a large storage capacity.

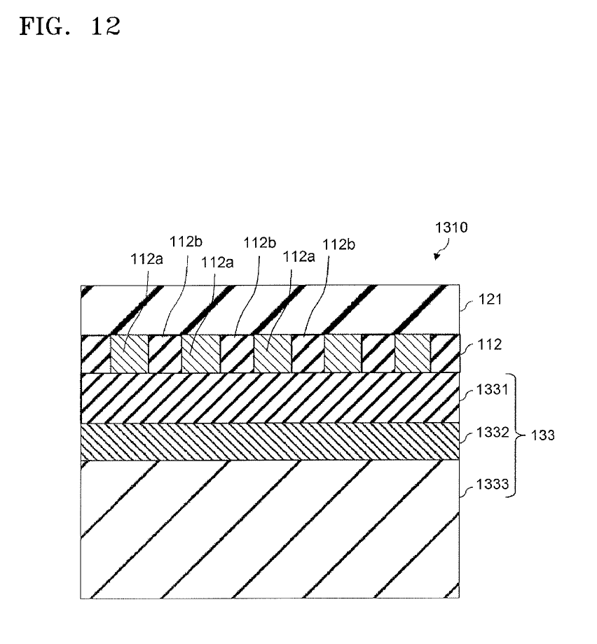

FIG. 12 illustrates a sectional view of another embodiment of an MTJ device 1310. This embodiment may be the same as the MTJ device 1210 of FIG. 11, except for the fixed layer. As illustrated in FIG. 12, the MTJ device 1310 has a stack structure of a fixed layer 133, a spacer layer 112, and a memory layer 121 in this order.

The fixed layer 133 has a stack structure of stacking a perpendicular magnetization holding layer 1333, a magnetic coupling control layer 1332, and a ferromagnetic layer 1331 in this order. The ferromagnetic layer 1331 includes a ferromagnetic insulating layer including the same ferromagnetic insulator as the memory layer 111 of FIG. 9. The ferromagnetic layer 1331 has a perpendicular magnetic anisotropy constant Kᵤ₁. Furthermore, the ferromagnetic insulator may not maintain a magnetization direction perpendicular to a film surface, unlike the ferromagnetic insulator forming the fixed layer 123 of FIG. 11.

The magnetic coupling control layer 1332 includes a material having an influence on magnetic coupling of the ferromagnetic layer 1331 and the perpendicular magnetization holding layer 1333. The material may be, for example, Rh, Pd, Pt, Ru, or MgO. The thickness of the magnetic coupling control layer 1332 may be, for example, 2 nm or less. The thickness may be different in another embodiment. Changing the thickness of the magnetic coupling control layer 1332 may adjust one or more factors, including but not limited to MR ratio (a resistance changing rate), heat stability, recording current, or magnetization reversal speed.

The perpendicular magnetization holding layer 1333 includes a material having a perpendicular magnetic anisotropy constant Kᵤ₂. The perpendicular magnetic anisotropy constant Kᵤ₂ is higher than the perpendicular magnetic anisotropy constant Kᵤ₁ of the ferromagnetic layer 1331. The material may be, for example, FePd or FePt of L10 type.

The MTJ device 1310 includes the magnetic coupling control layer 1332 in the fixed layer 133. However, the magnetic coupling control layer 1332 may be excluded from the fixed layer 133 in another embodiment. For example, the MTJ device 1310 may include a fixed layer laminating the perpendicular magnetization holding layer 1333 and the ferromagnetic layer 1331 in this order, instead of the fixed layer 133.

In a data reading operation, reading current flows from the fixed layer 133 to the memory layer 121. More electrons having a spin parallel (or anti-parallel) to the magnetization direction of the fixed layer 133 flow into the fixed layer 133. Thus, a spin filter effect is provided, and the higher the spin polarizability, the higher the MR ratio. As the MR ratio increases, a signal voltage from the MTJ device 1310 also increases. Thus, the MTJ device 1310 has excellent data reading performance. Also, an MRAM using the MTJ device 1310 may have a large storage capacity. Furthermore, when the ferromagnetic layer 1331 includes a ferromagnetic insulating layer including a ferromagnetic insulating oxide, such as CoxFe_{3-X}O₄, having a higher magnetic anisotropy, the memory layer 121 may have high heat stability to magnetization during a data reading operation.

In a data writing operation, when a writing current flows into the bit line 1, writing current flows into the MTJ device 1310. Then, the temperature of the fixed layer 133 increases. The temperature of the memory layer 121 may also increase because the fixed layer 133 has insulating properties. Therefore, a state occurs where it is easy to reduce magnetic anisotropy and reverse a magnetization direction of the memory layer 121. Furthermore, the magnetization direction of the memory layer 121 is changed to a predetermined direction due to spin-torque transmission in the memory layer 121 by the current flowing into the MTJ device 1310. Therefore, it is possible to write data corresponding, for example, to data 0 or data 1, in the memory cell 100. Also, it may be possible to reverse the magnetization direction by a low current density in the MTJ device 1310, as well as in the MTJ device 1210.

In this embodiment and the previous embodiment, the MTJ device may have low magnetization reversal current density. Furthermore, the MTJ device has a high MR ratio and excellent data reading performance. Moreover, the MTJ device may form a MRAM having a large storage capacity.

Furthermore, in this embodiment, it is possible to adjust the MR ratio (a resistance changing rate), heat stability, recording current, magnetization reversal speed, and/or another factor by adjusting the thickness of magnetic coupling control layer 1332.

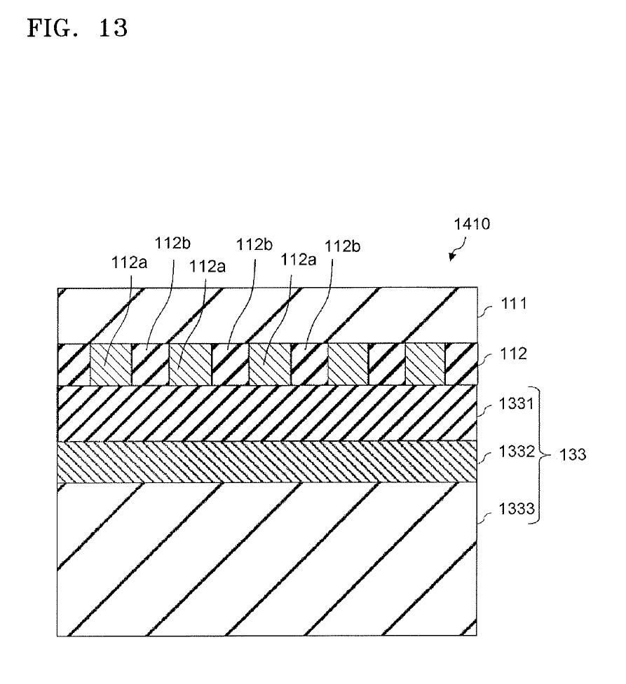

FIG. 13 illustrates a sectional view of another embodiment of an MTJ device 1410. This embodiment is the same as the MTJ device 110 of FIG. 9, except for the fixed layer. As illustrated in FIG. 13, an MTJ device 1410 has a stack structure of a memory layer 111, a spacer layer 112, and a fixed layer 133 in this order. The fixed layer 133 is the same as the MTJ device 1310 of FIG. 12.

In a data writing operation, a memory cell using the MTJ device 1410 receives writing current from a writing circuit according to written data. For example, when the writing current flows into the bit line 1, writing current flows into the MTJ device 1410. Then, the magnetization direction of the memory layer 111 is changed to a predetermined direction, as well as the MTJ device 110 of FIG. 9. Therefore, it is possible to write data corresponding, for example, to data 0 or data 1, in the memory cell 100. The MTJ device 1410 has low magnetization reversal current density as well as the MTJ device 110. An MRAM including the MTJ device has low power consumption.

In a data reading operation, reading current flows from the fixed layer 133 to the memory layer 111. More electrons having a spin parallel (or anti-parallel) to the magnetization direction of the fixed layer 133 flows into the fixed layer 133. Thus, a spin filter effect is provided, and the higher the spin polarizability, the higher the MR ratio. As the MR ratio increases, a signal voltage from the MTJ device 1410 also increases. Thus, the MTJ device 1410 has excellent data reading performance. An MRAM using the MTJ device 1410 has a large storage capacity. Furthermore, when the ferromagnetic layer 1331 includes a ferromagnetic insulating layer including a ferromagnetic insulating oxide, such as CoxFe_{3-X}O₄, having a higher magnetic anisotropy, the memory layer 111 may have high heat stability to magnetization during a data reading operation.

In this embodiment, the MTJ device may reverse a magnetization direction of the memory layer 111 even by a low current density. Furthermore, the MTJ device may have a high MR ratio, and thus may have excellent data reading performance. Moreover, the MRAM including the MTJ device may reverse the power consumption.

In another embodiment, one or more of the aforementioned embodiments of the MTJ device may include a memory layer laminating a perpendicular magnetization holding layer and a ferromagnetic layer, instead of the existing memory layer. Furthermore, the MTJ device 1210 of FIG. 11 may include a memory layer including a ferromagnetic insulator instead of the memory layer 121. Also, one or more of the aforementioned embodiments of the MTJ device have the spacer layer 112. However, in one or more other embodiments, a spacer layer memory layer may also be included, with a columnar part including a non-magnetic insulator and a matrix including a non-magnetic metal.

By way of summation and review, an MTJ device may perform a data reading operation based on a magnetroresistance effect and may perform a data writing operation using a spin transfer torque (STT) method. This type of device includes a memory layer having a variable magnetization direction, a fixed layer that maintains a magnetization direction perpendicular to a film surface, and a tunnel barrier layer including an insulator between the memory layer and the fixed layer. In one arrangement, a ferromagnetic material having high perpendicular magnetic anisotropy and high spin polarizability may be used to form the fixed layer and memory layer. Such an MTJ device may also have a thermal disturbance resistance that corresponds to microfabrication.

Also, an MTJ device has been developed to include an anti-ferromagnetic film on at least one side of a fixed layer. A ferromagnetic metal such as cobalt (Co), iron (Fe), nickel (Ni), their alloys, or an alloy having B such as CoFeB is used to form the fixed layer and memory layer.

Another type of MTJ device has a stacked arrangement of a memory layer, a non-magnetic layer, and a fixed layer. The memory layer includes a magnetic substance film formed of an underlying layer and a Mn—Ga based alloy. The fixed layer includes a magnetic substance film formed of a Mn—Ga based alloy.

These devices have drawbacks. For example, they do not reduce a magnetization reversal current for reversing a magnetization direction of the memory layer. Furthermore, ferromagnetic metals, their alloys, or a Mn—Ga based alloy are used as the ferromagnetic material having high perpendicular magnetic anisotropy and high spin polarizability. These materials may not be suitable for all applications.

In accordance with one or more of the aforementioned embodiments, an MTJ device is capable of reversing a magnetization direction of a memory layer even by a low current density. The MTJ device may use at least one of a memory layer or a fixed layer as a ferromagnetic insulator. Then, the temperature of the memory layer increases during magnetization reversal. Thus, the magnetic anisotropy is reduced. Furthermore, it is possible to more surely reverse the magnetization direction of the memory layer, even by a low current density, by forming a spacer layer between the memory layer and the fixed layer with current paths and an insulator.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the invention as set forth in the following claims.

What is claimed is:

1. A magnetic tunnel junction device, comprising:
a memory layer having a variable magnetization direction;
a fixed layer maintaining a predetermined magnetization direction; and
a spacer layer between the memory layer and the fixed layer, wherein the magnetic tunnel junction device is to perform a data writing operation using a spin torque injection method and wherein at least one of the memory layer or the fixed layer includes a ferromagnetic insulating layer.

2. The device as claimed in claim 1, wherein the memory layer and the fixed layer include ferromagnetic insulating layers.

3. The device as claimed in claim 1, wherein:
the memory layer includes the ferromagnetic insulating layer, and
the ferromagnetic insulating layer has perpendicular magnetic anisotropy.

4. The device as claimed in claim 1, wherein the memory layer includes:
the ferromagnetic insulating layer; and
a perpendicular magnetization holding layer having a magnetization direction perpendicular to a film surface.

5. The device as claimed in claim 1, wherein:
the fixed layer includes the ferromagnetic insulating layer, and
the ferromagnetic insulating layer has perpendicular magnetic anisotropy.

6. The device as claimed in claim 1, wherein the fixed layer includes:
the ferromagnetic insulating layer; and
a perpendicular magnetization holding layer having a magnetization direction perpendicular to a film surface.

7. The device as claimed in claim 1, wherein the ferromagnetic insulating layer includes a ferromagnetic oxide.

8. The device as claimed in claim 1, wherein the ferromagnetic insulating layer includes BaFe₁₂O₁₉ or CoxFe_{3-X}O₄, where 0<x<3.

9. The device as claimed in claim 1, wherein a device resistance value of the magnetic tunnel junction device is about 30 Ωμm² or less.

10. The device as claimed in claim 1, wherein the spacer layer includes:
a plurality of current paths electrically connecting the memory layer to the fixed layer; and
an insulator electrically insulating the memory layer from the fixed layer.

11. The device as claimed in claim 10, wherein:
the current paths include columnar bodies having a non-magnetic metal,
the insulator includes a matrix surrounding each of the current paths, and
the matrix includes a non-magnetic insulator.

12. The device as claimed in claim 11, wherein the non-magnetic insulator includes MgO or Al₂O₃.

13. The device as claimed in claim 11, wherein the non-magnetic metal includes Cu.

14. A magnetoresistive random access memory, comprising:
the magnetic tunnel junction device as claimed in claim 1.

15. A magnetoresistive random access memory, comprising:
the magnetic tunnel junction device as claimed in claim 10.

16. A magnetic tunnel junction device, comprising:
a memory layer having a variable magnetization direction;
a fixed layer maintaining a predetermined magnetization direction; and
a plurality of current paths electrically connecting the memory layer and the fixed layer, wherein at least one of the memory layer or the fixed layer includes a ferromagnetic insulating layer.

17. The device as claimed in claim 16, wherein the magnetic tunnel junction device is to perform a data writing operation using a spin torque injection method.

18. The device as claimed in claim 16, wherein the ferromagnetic insulating layer has perpendicular magnetic anisotropy.

19. The device as claimed in claim 16, wherein the memory layer includes:
the ferromagnetic insulating layer; and
a perpendicular magnetization holding layer having a magnetization direction perpendicular to a film surface.

20. The device as claimed in claim 17, wherein the fixed layer includes:
the ferromagnetic insulating layer; and
a perpendicular magnetization holding layer having a magnetization direction perpendicular to a film surface.
